(19) United States
(12) Patent Application Publication
(10) Pub. No.: US 2005/0212018 A1
(43) Pub. Date: Sep. 29, 2005

(54) Conductive lines buried in insulating areas

(75) Inventors: Jean-Pierre Schoellkopf, Grenoble (FR); Robin Cerutti, Grenoble (FR); Philippe Coronel, Barraux (FR); Thomas Skotnicki, Crolles-Montfort (FR)

Correspondence Address: STMicroelectronics Inc.;c/o WOLF, GREENFIELD & SACKS, PC, Federal Reserve Plaza, 600 Atlantic Avenue, BOSTON, MA, 02210-2206, US

(73) Assignee: STMicroelectronics S.A., Montrouge (FR)

(21) Appl. No.: 11/135,172

(22) Filed: May 23, 2005

Related U.S. Application Data
(62) Division of application No. 10/903,527, filed on Jul. 30, 2004.

(30) Foreign Application Priority Data
Jul. 30, 2003 (FR) 03/50382

(51) Int. Cl. H01L 29/76

(52) U.S. Cl. 257/288

(57) ABSTRACT

An integrated circuit comprising a semiconductor substrate in which active areas surround or are surrounded by hollowings filled with an insulator, and in which a conductive region is embedded in the insulator of at least one hollowing, the conductive region being connected to a reference voltage and being connected at least one neighboring element of the circuit.

### BACKGROUND OF THE INVENTION

1. Field of the Invention

The present invention relates to integrated circuits, and more specifically to networks of distribution of a reference voltage such as a supply voltage or the ground.

2. Discussion of the Related Art

An integrated circuit generally includes a network of distribution of supply voltage Vdd, a ground distribution network GND, and possibly networks of distribution of other reference voltages, for example, Vdd/2, formed above an integrated circuit. The conductive lines of the distribution networks belong to the conductive lines of the integrated circuit's interconnect network. The conductive lines of the interconnect network are formed on several levels and are connected to one another by conductive vias. Each of the distribution networks is generally formed of relatively long and wide parallel rails formed on one of the levels of the integrated circuit's interconnect network. The space taken up by the lines of such distribution networks is relatively large, which results in limiting the space available for the other circuit lines generally intended to transmit signals. Now, due to the small possible room available for these lines, they are often narrow and accordingly exhibit a relatively high resistance, which is a disadvantage in certain circuits such as memories.

Generally, the reference voltage distribution requires providing conductive lines formed on the different levels of the interconnect network. The space taken up by the conductive distribution lines may become significant, which adversely affects the forming of connections intended to transmit signals.

A way to increase the available space for the “critical” connection lines consists of increasing the number of levels of the interconnect network. This solution is however expensive. Another way consists of decreasing the integration density of components in the integrated circuit substrate to have more space above the components, but this solution goes against the progress of technology.

### SUMMARY OF THE INVENTION

An object of the present invention is to provide a structure of conductive lines dedicated to the distribution of a reference voltage which enables significantly increasing the space available for forming the connections intended to transmit signals.

Another object of the present invention is to provide a method for forming such conductive lines dedicated to the distribution of reference voltages.

To achieve these and other objects, the present invention provides an integrated circuit comprising a semiconductor substrate in which active areas surround or are surrounded by hollowings filled with an insulator, and in which a conductive region is embedded in the insulator of at least one hollowing, the conductive region being connected to a reference voltage and being connected to at least one neighboring element of the circuit.

According to an embodiment of the above-mentioned integrated circuit, the conductive region is connected to a conductive supply or ground line of an interconnect network.

According to an embodiment of the above-mentioned integrated circuit, said element of the circuit is a terminal of a component or a bias contact of the substrate or of a well formed in the substrate.

According to an embodiment of the above-mentioned integrated circuit, the circuit comprises components formed in active areas, the substrate and the components being covered with an insulating protective layer, a portion of an active area adjacent to one of said at least one hollowing being connected to the conductive region of this hollowing via a metal contact placed in a single opening of the protection insulating layer and of the insulator covering the conductive layer.

According to an embodiment of the above-mentioned integrated circuit, the semiconductor substrate is made of single-crystal silicon, said insulator being formed of silicon oxide and nitride.

According to an embodiment of the above-mentioned integrated circuit, the circuit forms an SRAM-type memory, in which the supply and ground voltage distribution network is formed of a network of conductive regions embedded in several hollowings of the substrate, the conductive regions being connected to several source/drain areas of the MOS transistors of the memory by contacts.

The present invention also provides a method for forming conductive lines buried in a substrate of an integrated circuit, comprising the steps of: forming hollowings in a semiconductor substrate and covering the bottom and the walls with an insulator; forming at the bottom of the hollowings layers of a sacrificial material; filling the hollowings with an insulator to form insulating layers above the layers of said sacrificial material; forming openings in the insulating layers; removing said sacrificial material; and filling with a conductive material the openings and the space previously taken up by said sacrificial material.

According to an embodiment of the above-mentioned method, the method comprises, after the third step, the steps of: forming components in some active areas of the substrate; covering the substrate and the components with a protection insulating layer; and forming openings in the protection insulating layer and in the insulating layers.

The foregoing objects, features, and advantages of the present invention will be discussed in detail in the following non-limiting description of specific embodiments in connection with the accompanying drawings.

### BRIEF DESCRIPTION OF THE DRAWINGS

FIG. 1 is a top view of an example of an integrated circuit portion;

FIG. 2 is a cross-section view along line AA′ of FIG. 1;

FIG. 3 is a cross-section view along line AA′ of FIG. 1 illustrating the present invention;

FIGS. 4 to 10 are cross-section views of structures obtained after different steps of the method of the present invention;

FIGS. 11 and 12 are two examples of top views of the structure of FIG. 10;

FIGS. 13 to 20 are cross-section views of the structures obtained after different steps of a specific implementation mode of the method of the present invention;

FIG. 21 is a diagram of a memory point of SRAM type;

FIG. 22 is a simplified top view of a SRAM memory point according to the present invention;

FIG. 23 is a cross-section view of the memory point of FIG. 22;

FIG. 24 is a simplified top view of an external portion of a SRAM-type memory; and

FIG. 25 is a simplified top view of an internal portion of a SRAM-type memory.

### DETAILED DESCRIPTION

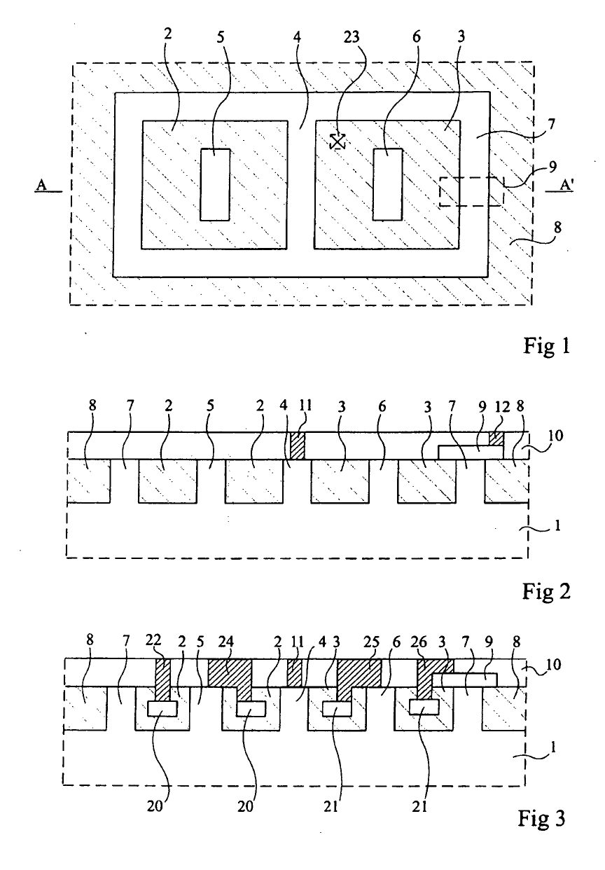

For clarity, the same elements have been designated with the same reference numerals in the different drawings. Further, as current in the representation of integrated circuits, FIGS. 1 to 20, 22, and 23 are not drawn to scale.

FIGS. 1 and 2 respectively are a top view and a cross-section view of an example of a portion of a conventional integrated circuit formed in a semiconductor substrate 1. Hollowings are formed at the surface of substrate 1. These hollowings are filled with an insulating material. The insulator-filled hollowings form insulation areas currently called STI areas, for shallow trench insulation. The insulating areas are hatched. The substrate portions surrounding or surrounded by insulating areas form active areas. In this circuit portion example, two square insulation areas 2 and 3 are separated by a rectangular active area 4. Two rectangular active areas 5 and 6 are placed in each of insulating areas 2 and 3. Insulating areas 2, 3 and active area 4 are surrounded with a substantially rectangular active area 7. An insulation area 8 surrounds active area 7. As an example, a polysilicon area 9, shown in dotted lines in FIG. 1, is placed perpendicular to the portion of active area 7 shown to the right of FIG. 1. Area 9 is separated from active area 7 and from insulation areas 3 and 8 by a thin oxide layer. Area 9 forms the gate of a MOS transistor having its source and drain formed in active area 7 on either side of area 9.

Various components not shown are formed in and above the active areas. Substrate 1 and insulation areas 2, 3, and 8 are covered with an insulating layer 10. As an example, a contact 11 is placed in an opening of insulating layer 10 above active area 4. Similarly, a contact 12 is placed in an opening of insulating layer 10 above polysilicon area 9. Contacts 11 and 12 enable connecting active area 4 and polysilicon area 9 to a component of the integrated circuit or to a supply terminal via an interconnect network, not shown, placed above insulating layer 10.

FIG. 3 is a cross-section view of an example of an integrated circuit according to the present invention having a top view identical to that shown in FIG. 1. The cross-section view is made as for FIG. 2 along axis AA′.

The integrated circuit of the present invention comprises conductive regions 20 and 21 embedded in insulation areas 2 and 3, and thus insulated from substrate 1. In this example, no conductive region is placed inside of insulation area 8.

A contact 22 is placed in two superposed openings of insulating layer 10 and of the portion of insulation area 2 above conductive layer 20. Similarly, a contact 23, shown by a cross in a square in dotted lines in FIG. 1, is placed in two superposed openings of insulating layer 10 and of the right-hand portion of insulation area 3 above conductive layer 21. Contacts 22 and 23 are connected to the interconnect network, not shown. Conductive layers 20 and 21 are thus each connected to a reference voltage, for example, a supply voltage and the ground, via contacts 22 and 23.

Further, a contact 24 is placed in two superposed openings of insulating layer 10 and of the right-hand portion of insulating area 2. The opening of insulating layer 10 is formed above the left-hand portion of insulation area 2 and above the right-hand portion of active area 5. Similarly, a contact 25 is placed in two superposed openings of insulating layer 10 and of the left-hand portion of insulation area 3. The opening of insulating layer 10 is formed above the right-hand portion of the left-hand portion of insulation area 3 and above the left-hand portion of active area 6. Contacts 24 and 25 thus enable connecting conductive layers 20 and 21 respectively to selected regions of active areas 5 and 6.

A contact 26 is placed in two superposed openings of insulating layer 10 and of the right-hand portion of insulation area 3. The opening of insulation area 10 is formed above and on the side of the left-hand portion of polysilicon area 9. Contact 26 thus enables connecting conductive layer 21 to gate area 9 of the transistor.

Thus, an integrated circuit according to the present invention comprises conductive regions placed inside of certain insulation areas surrounding or surrounded by active areas. The conductive regions are biased to a reference voltage and connected to chosen regions of one or several components of an integrated circuit via a contact placed above the conductive regions.

An advantage of an integrated circuit structure according to the present invention is that it enables integrating a reference voltage distribution network in an integrated circuit without modifying its structure, that is, without increasing the number of levels of the interconnect network and without decreasing the component integration density in the substrate.

The present invention further provides a method for forming an integrated circuit comprising, like the circuit of FIG. 3, buried conductive lines in the insulation areas formed in the circuit substrate.

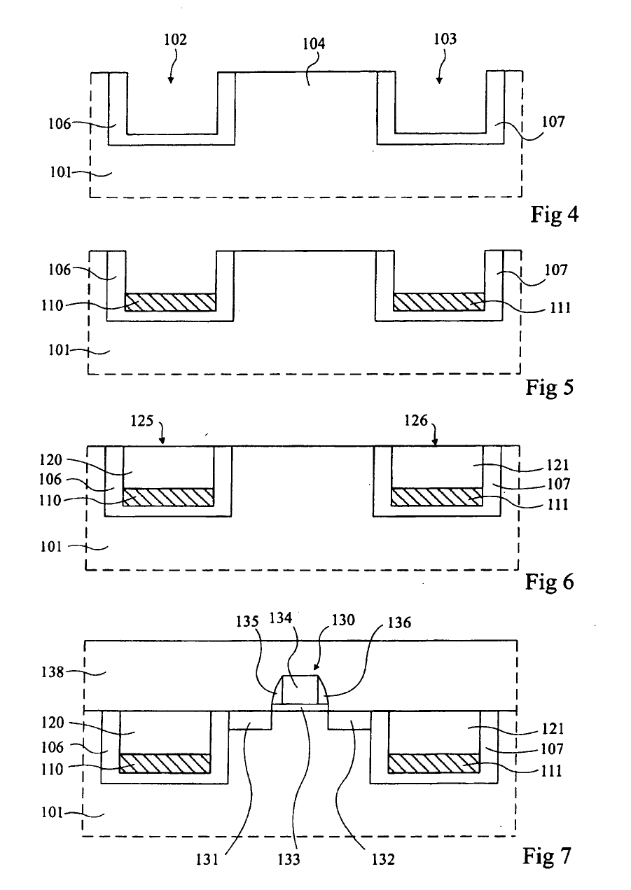

In a first step, illustrated in FIG. 4, hollowings 102 and 103 are formed in a substrate 101, for example, made of single-crystal silicon. Hollowings 102 and 103 are separated by a substrate portion corresponding to an active area 104. The bottom and the walls of hollowings 102 and 103 are respectively covered with insulating layers 106 and 107. Insulating layers 106 and 107 may be formed of a single insulator or of several insulators such as silicon oxide (SiO₂) and silicon nitride (Si₃N₄).

At the next step, illustrated in FIG. 5, a sacrificial layer 110, 111, formed of a material selectively etchable with respect to substrate 101 and insulators 106 and 107, is formed in each of hollowings 102 and 103. Silicon/germanium sacrificial layers may for example be formed when the substrate is made of silicon. A method for forming layers 110 and 111 comprising performing a silicon/germanium deposition over the entire structure to completely fill hollowings 102 and 103, then of polishing the silicon/germanium according to a standard chem.-mech polishing method to expose the upper surface of substrate 101, and of finally performing a partial etch of the silicon/germanium portions filling hollowings 102 and 103 to keep a silicon/germanium layer in the bottom of each hollowing.

At the next step, illustrated in FIG. 6, an insulating layer is formed in each of hollowings 102 and 103. Intermediary layers 110 and 111 are thus respectively covered with insulating layers 120 and 121. A method for forming insulating layers 120 and 121 comprising performing an insulator deposition over the entire structure to completely fill hollowings 102 and 103 and to perform a chem.-mech polishing of the deposited insulator to expose the upper surface of substrate 101. To ensure that hollowings 102 and 103 are effectively filled with an insulator, a composite technique associating a deposition and an etching which enables avoiding for “holes” to form in the silicon oxide layer when the hollowing is deep and not very wide, may be used.

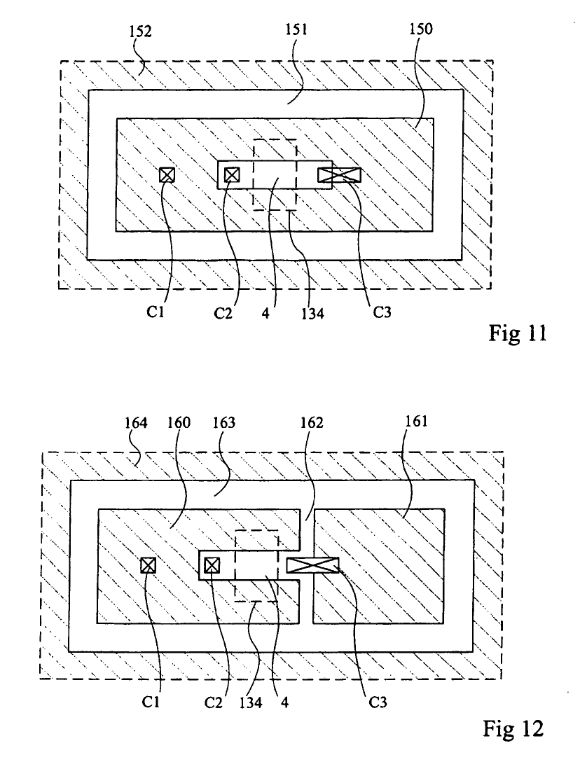

Insulating layers 106 and 120 belong to a portion 125 of an insulation area. Similarly, insulating layers 107 and 121 belong to a portion 126 of an insulation area. Portions 125 and 126 may belong to different insulation areas or to a same insulation area as will appear from the following description in relation with FIGS. 11 and 12.

At the next step, illustrated in FIG. 7, components are conventionally formed in and above active area 104. In this example, a MOS transistor 130 is formed. Source/drain areas 131 and 132 are respectively formed in the vicinity of insulation areas 125 and 126. The portion of substrate 101 placed between source/drain areas 131 and 132 is covered with a gate oxide 133 itself covered with a gate 134. Insulating spacers 135 and 136 are formed on the sides of gate 134. The entire structure is then covered with a protective insulating layer 138.

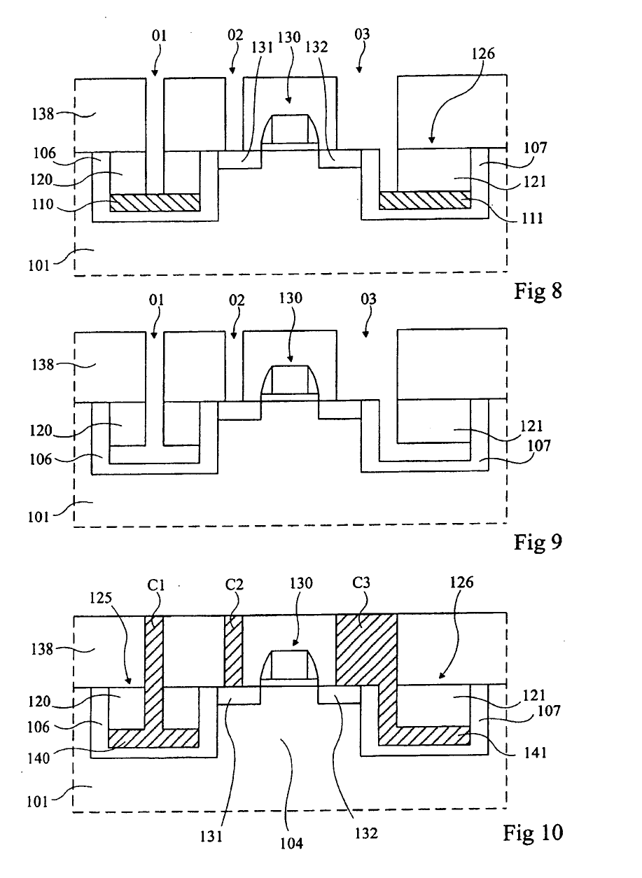

At the next step, illustrated in FIG. 8, openings are formed in insulating layer 138 and in insulating layers 120 and 121, for example, by etching. In this example, an opening O1 is formed in insulating layers 138 and 120 above intermediary layer 110 to expose a central portion of layer 110. An opening O2 is formed in insulating layer 138 above source/drain area 131. An opening O3 is formed in insulating layers 138 and 121 above source/drain area 132 and insulating area 126 to expose a portion of source/drain area 132, the upper surface of insulating layer 107, and a portion of intermediary layer 111. For reasons which will appear hereafter, the areas of insulating layers 106 and 107 exposed by this etch step must be formed of a insulator different from that of insulating layers 138, 120, and 121 not to be etched upon forming of openings O1, O2, and O3.

At the next step, illustrated in FIG. 9, sacrificial layers 110 and 111 are removed, for example, by etching. In the case where layers 110 and 111 are made of silicon/germanium and the substrate made of silicon, a method for selectively etching the silicon/germanium with respect to silicon is chosen. At the end of this step, “tunnels” have been formed under insulating layers 120 and 121.

At the next step, illustrated in FIG. 10, the previously-formed tunnels and openings O1, O2, and O3 are filled with a conductive material such as aluminum, tungsten W, or titanium nitride TiN. Conductive layers 140 and 141 have thus been formed within insulating areas 125 and 126 as well as contacts C1, C2, and C3 in openings O1, O2, and O3. Conductive layer 141 is thus connected to source/drain area 132 of transistor 130 via contact C3. As mentioned hereabove in the step of etching openings O1 to O3, the portion of insulating layer 107 placed against active area 104 must be kept intact to avoid any short-circuit between conductive layer 141 or contact C3 and substrate 101.

Contact C1 is then connected, for example, to a reference voltage and contact C3 is then connected to a component of the integrated circuit formed in substrate 101 or to a terminal of the integrated circuit via an interconnect network, not shown, which is formed above insulating layer 138.

According to an alternative of the method of the present invention, layers 110 and 111 deposited at the bottom of the hollowings are no longer sacrificial but definitive layers. Layers 110 and 111 are then formed of a conductive material. Once the openings have been formed above the conductive layers, a metal contact is directly formed in the opening. This alternative is much simpler but it is not recommended in the case where the conductive material cannot resist the high temperatures of the component-forming steps. Further, the material should not be likely to diffuse into the substrate in the high-temperature steps to avoid damaging the integrated circuit components. Layers 110 and 111 of titanium nitride, which is a stable material, may for example be formed.

FIGS. 11 and 12 are two examples of top views of the structure shown in FIG. 10. In both drawings, active area 4 is a small rectangular area. Gate 134, shown in dotted lines, is placed perpendicular to active area 4. Contact C2 is placed above active area 4.

The structure of FIG. 11 comprises a rectangular insulation area 150 surrounding active area 4. A thin active area 151 surrounds insulation area 150 which is itself surrounded with an insulation area 152. Contact C1 is placed above insulation area 150 in prolongation of active area 4. Contact C3 is placed above active area 4 and insulation area 150. In this circuit example, the two portions of insulation areas 125 and 126 placed under contacts C1 and C3 belong to the same insulation area 150.

The structure of FIG. 12 comprises two substantially rectangular areas 160 and 161 separated from each other by a thin rectangular active area 162. One of the sides of active area 4, where is formed source/drain area 132, is adjacent to active area 162 on the side of insulation area 160. Insulation area 160 thus partially surrounds active area 4. Insulation areas 160 and 161 are surrounded with a thin active area 163, itself surrounded with an insulation area 164. Contact C1 is placed above insulation area 160 in prolongation of active area 4 on the side opposite to active area 162. Contact C3 is placed above active area 4 and insulation area 161. In this circuit example, the two portions of insulation area 125 and 126 placed under contacts C1 and C3 belong to different insulation areas.

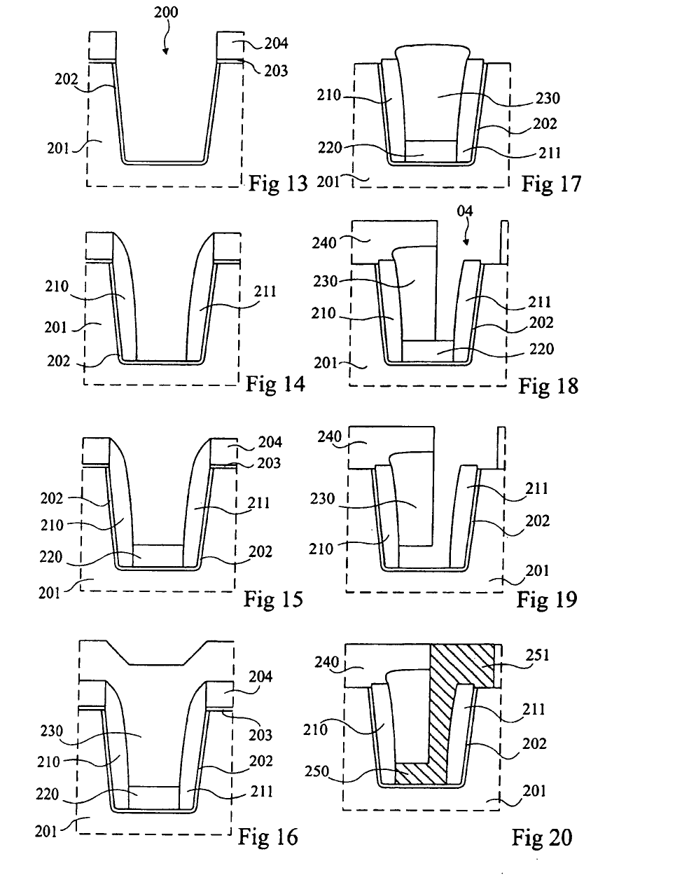

FIGS. 13 to 20 are cross-section views of structures obtained after different steps of an implementation mode of the method of the present invention integrated to a standard method for forming shallow insulation areas, better known as STI, for shallow trench insulation. The conventional STI forming method includes oxidizing a silicon substrate to form a thin silicon oxide layer which is covered with a nitride layer followed by a masking layer formed for example of a densified silicon oxide (TEOS). The mask is then covered with a resist layer which is insolated and developed to define areas where a substrate hollowing is desired to be formed. A series of etches, successively of the mask, of the nitride layer, of the thin silicon oxide layer, and of the substrate is then performed. Then, the resist and the mask are removed. A silicon oxide layer is then grown at the bottom and on the walls of the hollowings previously formed in the substrate.

FIG. 13 is a cross-section view of a structure obtained after all the above-described operations. A hollowing 200 is formed in a substrate 201. The bottom and the walls of hollowing 200 are covered with a thin silicon oxide layer 202. On the sides of hollowing 200, substrate 201 is covered with a silicon oxide layer 203, itself covered with a nitride layer 204.

At the next step, illustrated in FIG. 14, nitride spacers 210 and 211 are formed against the walls of hollowing 200. Spacers 210 and 211 are, for example, formed according to a conventional method consisting of performing a conformal nitride deposition, then of performing an anisotropic etch of the nitride to, in this example, expose thin silicon oxide layer 202 at the bottom of hollowing 200.

At the next step, illustrated in FIG. 15, an intermediary layer 220, made of silicon/germanium in this example, is formed at the bottom of hollowing 200 according to a method identical to that described in relation with FIG. 5.

At the next step, illustrated in FIG. 16, a deposition of an insulator is performed above the structure, to integrally fill hollowing 200. The deposited insulator conventionally is silicon oxide deposited according to a composite deposition/etch technique avoiding the forming of “holes”.

At the next step, illustrated in FIG. 17, a chem.-mech polishing of insulating layer 230 is performed to expose nitride layer 204. An anisotropic etch of nitride layer 204 and of spacers 210 and 211 is then performed to expose silicon oxide layer 203. A silicon oxide etch is then performed to completely remove silicon oxide layer 203. In the two etches, the thickness of insulating layer 230 decreases more or less according to the implemented etch methods.

Components are then formed in and above the active areas of substrate 201, not shown, separated from one another by hollowings identical to hollowing 200.

At the next step, illustrated in FIG. 18, the entire structure is covered with an insulating layer 240. Then, an opening O4 is etched in insulating layers 240 and 230 above a portion of substrate 201, of spacer 211, and of a portion of intermediary layer 220.

At the next step, illustrated in FIG. 19, intermediary layer 220 is removed according to a method identical to that described in relation with FIG. 9.

At the next step, illustrated in FIG. 20, opening O4 and the space previously taken up by layer 220 are filled with a conductive material. A conductive layer 250 has thus been formed at the bottom of hollowing 200 and a contact 251 is formed in opening O4. Conductive layer 250 is connected to a substrate portion via contact 251.

The steps previously described in relation with FIGS. 14, 15, 18, 19, and 20 add to the steps of the standard method of formation of shallow trench insulation or STI areas. These additional steps may be implemented on all or part of the integrated circuit. If buried lines are desired to be formed in a portion only of the circuit insulation areas, it is necessary to provide additional steps of “masking” and “unmasking” of the insulation areas where buried lines are not desired to be incorporated.

An example of embodiment of an integrated circuit according to the present invention is a memory of SRAM type described hereabove.

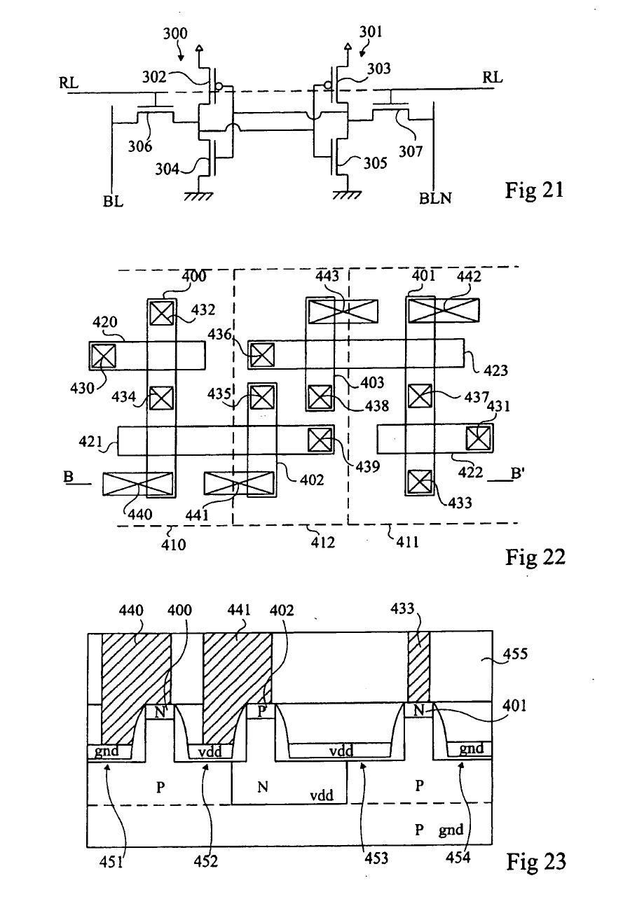

FIG. 21 is a conventional diagram of a SRAM memory point. The memory point comprises two inverters 300 and 301, each formed of a PMOS transistor 302 and 303 and of an NMOS transistor 304 and 305. The gates of transistors 302 and 304 of inverter 300 are interconnected and connected to the drains of transistors 303 and 305 of inverter 301. Similarly, the gates of transistors 303 and 305 of inverter 301 are interconnected and connected to the drains of transistors 302 and 304 of inverter 300. The sources of PMOS transistors 302 and 303 are connected to a supply voltage Vdd. The sources of NMOS transistors 304 and 305 are connected to ground GND. The drains of transistors 302 and 304 are connected to a bit line BL via an NMOS transistor 306. Similarly, the drains of transistors 303 and 305 are connected to a complementary bit line BLN via an NMOS transistor 307. The gates of transistors 306 and 307 are connected to a row line RL.

A SRAM conventionally comprises a array of memory points such as that of FIG. 21 that can be selected by means of several row lines and of several pairs of bit lines BL/BLN. The operation of such an SRAM is known and will not be described in detail.

FIG. 22 is a simplified top view of the SRAM memory point of FIG. 21. The memory point is formed in a P-type substrate. Active areas of the substrate are represented by vertical rectangles. The transistor gates are represented by horizontal rectangles. Insulation areas are formed everywhere active areas are not shown. The contacts are represented by a square or a rectangle in which is placed a cross. Generally, an NMOS or PMOS transistor is formed of a vertical active area and of a horizontal gate area intersecting perpendicularly. In the case of an NMOS transistor, the portions of the active area located on either side of the gate area are doped of type N. For a PMOS transistor, the portions of the active area located on either side of the gate area are P-type doped.

The active areas corresponding to NMOS transistors 304 and 306 form a single vertical rectangular active area 400 placed to the left of FIG. 22 within a P well area 410 shown in dotted lines. Similarly, the active areas of NMOS transistors 305 and 307 form a single active area 401 of same shape as area 400, but placed to the right of FIG. 22 within a P well area 411 shown in dotted lines. Two active areas 402 and 403 corresponding to PMOS transistors 302 and 303 are placed between active areas 400 and 401 within an N well area 412 shown in dotted lines. Active area 402 corresponding to PMOS transistor 302 is placed to the bottom left of the area of N well 410 and area 403 corresponding to PMOS transistor 303 is placed to the top left of N well area 412. A gate area 420, corresponding to the gate of transistor 306, intersects active area 400 on the top of the drawing. A gate area 421, corresponding to the gate of transistors 302 and 304, is placed perpendicular to active areas 400 and 402 at the bottom of the drawing. A gate area 422, corresponding to the gate of transistor 307, intersects area 401 at the bottom of the drawing. A gate area 423, corresponding to the gates of transistors 303 and 305, is placed perpendicular to active areas 401 and 403 on the top of the drawing.

Two contacts 430 and 431 are placed respectively to the left of area 420 and to the right of area 422. Contacts 430 and 431 enable connecting the gates of transistors 306 and 307 to row line RL, not shown. Two contacts 432 and 433 respectively placed on the top of area 400 and on the bottom of area 401 enable connecting transistors 306 and 307 to bit lines, respectively BL and BLN. Three contacts 434, 435, and 436 respectively placed in the middle of active area 400, on the top of active area 402, and to the left of active area 423 are interconnected via a metal connection, not shown. Similarly, three contacts 437, 438, and 439, respectively placed in the middle of active area 401, on the bottom of active area 403 and to the right of active area 439 are connected by a metal connection not shown. A contact 440 is placed above the lower portion of active area 400 and extends to the left above an insulating area. A contact 441 is placed above the lower portion of active area 402 and extends to the left above an insulation area. A contact 442 is placed above the upper portion of active area 401 and extends to the right above an insulation area. A contact 443 is placed above the upper portion of active area 403 and extends to the right above an insulation area.

FIG. 23 is a cross-section view of the memory point shown in FIG. 23 along an axis B-B′ intersecting contacts 440, 441, and 433. Active areas 400, 402, and 401 are formed at the surface of P-type substrate 450. Active areas 400, 401, and 402 are separated by insulation area portions. A conductive region is placed inside of each of the insulation areas. Four insulation area portions 451, 452, 453, and 454 are visible from left to right. The conductive regions placed in portions 452 and 453 respectively between active areas 400 and 402 and between active areas 402 and 401 are both connected to a supply voltage Vdd. Conductive regions placed in portions 451 and 454 respectively placed to the left of active area 400 and to the right of active area 401 are both connected to ground GND. N-type well 412 is placed under active area 402 and under a portion of insulation areas 452 and 453. P-type wells 410 and 411 are placed respectively to the left and to the right of N-type well 412. The insulation areas and the active areas are covered with an insulating layer 455. Contacts 440, 441, and 433 are placed in openings of insulating layer 455. Contact 440 covers active area 400, the insulating layer placed against the walls of insulating area 451 and the conductive region connected to GND placed within insulation area 451. The portion of active area 400 corresponding to the source of transistor 304 is thus connected to ground GND via contact 440. Similarly, contact 441 covers active area 402, the insulating layer placed against the walls of insulation area 452, and the conductive region connected to Vdd placed at the bottom of the same area 452. The portion of active area 402 corresponding to the source of transistor 302 is thus connected to supply Vdd via contact 441. Contact 433 is conventionally placed above the portion of active area 401 corresponding to a source/drain area of transistor 307.

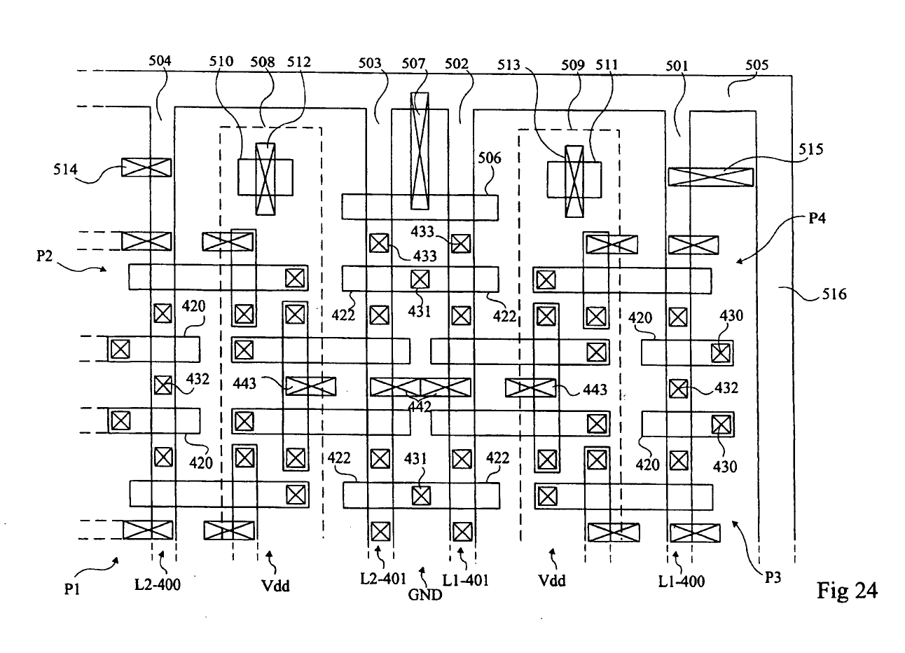

FIG. 24 is a simplified top view of a portion of a SRAM formed of a set of memory points of a composition identical to that of the memory point described in relation with FIGS. 21 to 23. The memory points are placed next to one another to form memory point rows and columns. In this example, four memory points P1 to P4 are shown. Point P1 is shown to the bottom left of the drawing with a structure and an orientation identical to the memory point shown in FIG. 22. Point P2 has a structure symmetrical to point P1 with respect to a horizontal axis. Point P2 is placed above point P1 so that contacts 432, 433, and 442 of each of the points are like superposed and in fact only form three contacts. Point P3 has a structure symmetrical to that of point P1 with respect to a vertical axis. Point P3 is placed to the right of point P1 so that contacts 431 of each of the points are superposed and form one and the same contact, and so that contacts 442 are adjacent. Point P4 has a structure symmetrical to that of point P3 with respect to a horizontal axis. Point P4 is placed above point P3 so that their contacts 432, 443, and 442 are “superposed”. Further, point P4 is placed to the right of point P2 so that their contacts 431 are “superposed” and their contacts 442 are adjacent. The pairs of points P1/P2 and P3/P4 respectively belong to two different vertical columns. The pairs of points P1/P3 and P2/P4 belong to two different horizontal rows. In this example, points P1 to P4 belong to the two higher rows of the memory and to the two rightmost columns of the memory. Active areas 400 of points P3 and P4 are adjacent to each other to form a continuous vertical active line L1-400 that extends downwards in areas 400 of other memory points, not shown, of the same column. Similarly, areas 401 of points P3 and P4 are adjacent to each other to form a continuous vertical active line L1-401 that extends downwards into areas 401 of other memory points of the same column. Similarly, areas 400 and 401 of points P3 and P4 also form continuous vertical active lines L2-400 and L2-401 that extend downwards. The insulation areas located between vertical active lines L1-400 and L1-401 in fact form one and the same insulation area, the conductive region of which substantially has the shape of a rail connected to Vdd. Similarly, the insulation areas located between vertical active lines L2-401 and L2-400 form one and the same insulation area, the conductive region of which substantially has the shape of a rail connected to Vdd. The insulation areas located between vertical active lines L1-401 and L2-401 form one and the same insulation area, the conductive region of which substantially has the shape of a rail connected to GND.

Rails Vdd and GND end at the bottom and at the top of each of the columns of the SRAM. Two “stop” structures are placed at the top and at the bottom of the SRAM. The two structures are symmetrical to each other with respect to a horizontal axis. The upper stop structure is shown in FIG. 24. It comprises four vertical rectangular active areas 501, 502, 503, and 504 continuing vertical active lines L1-400, L1-401, L2-401, and L2-400 upwards. A horizontal active area 505 is adjacent to the upper portion of each of active areas 501 to 504. Rails Vdd and GND thus end at the level of active area 505. Active areas 501 to 505 are N-type doped and grounded. To avoid connecting bit lines BLN of points P2 and P4 to ground, a gate area 506 intersects active areas 502 and 503 perpendicularly above contacts 433 of points P2 and P4. A contact 507 is placed above the insulation area portion vertically delimited by active areas 502 and 503 and horizontally delimited by active area 505 and gate area 506. Contact 507 extends above active area 505 and above gate area 506. Contact 507 connects ground GND to active area 505, to gate area 506, and to rail GND placed in the portion of the above-mentioned insulation area. The NMOS transistors sharing the same gate area 506 are all non-conductive, which isolates bit lines BLN from the ground.

Similarly, N-type wells 412 of each of the memory points are adjacent to one another to form a single N-type vertical well. P-type wells 410 and 411 of two adjacent columns form a single vertical P-type well. To properly bias the vertical N-type well, N wells 412 of points P2 and P4 extend upwards respectively in wells 508 and 509. Active areas 510 and 511 are placed inside of N wells 508 and 509. Contacts 512 and 513 are placed perpendicularly to active areas 510 and 511. Contacts 512 and 513 connect supply Vdd to N-type wells 508 and 509 as well as to rails “Vdd”. Contacts 514 and 515 are respectively placed above active areas 504 and 501 and extend above the insulation area located to the left of active area 504 and above the insulation area located to the right of active area 501.

To form a rail GND to the right of the rightmost column and to the left of the leftmost column of the memory, a continuous vertical active line is placed on each side of the memory. In this example, a vertical active line 516 is placed to the right of contacts 430 of points P3 and P4. The upper portion of vertical active line 516 is adjacent to active area 505. The conductive regions of insulation areas located between the memory points and these vertical active lines form two rails GND. Contact 515 extends in this example to above active line 516. Contact 515 enables grounding active areas 516, 501, and 505 as well as rail GND placed to the right of the memory.

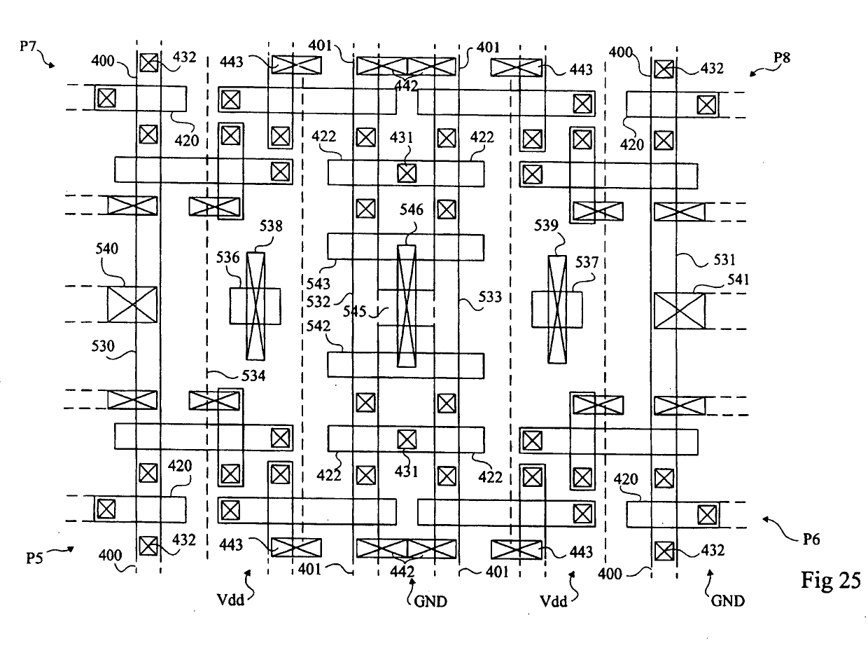

FIG. 25 is a simplified top view of another portion of the SRAM described hereabove. In the case where the SRAM comprises a large number of rows, the length of vertical rails GND and Vdd as well as of the N and P wells may be significant. It is then necessary to provide additional points of supply of each of the rails and of the wells by inserting, for example, supply relay blocks between two memory rows. Two memory points P5 and P6 belonging to a same row are shown at the bottom of the drawing. Point P5 has a structure and an orientation identical to that of the memory point shown in FIG. 22. Point P6 has a structure symmetrical to that of point P5 with respect to a vertical axis. Points P5 and P6 are adjacent to each other so that their contacts 431 form one and the same contact and that their contacts 442 are adjacent to each other. Similarly, two memory points P7 and P8 belonging to a same row are shown at the top of the drawing. Point P7 has a structure symmetrical to that of point P5 with respect to a horizontal axis. Point P8 has a structure symmetrical to that of point P7 with respect to a vertical axis. Points P7 and P8 are adjacent to each other so that their contacts 431 form one and the same contact and that their contacts 442 are adjacent.

The two shown rows are connected to each other by a relay block described hereafter. Active areas 400 of points P5 and P7 are connected by an active area 530. Similarly, active areas 400 of points P6 and P8 are connected by an active area 531. Active areas 401 of points P5 and P7 are connected by an active area 532. Active areas 401 of points P6 and P8 are connected by an active area 533. Active areas 530, 531, 532, and 533 are N-type doped. The N wells 412 of the pairs of points P5/P7 and P6/P8 are respectively connected by N wells 534 and 535. The P wells of points P5/P7 and P6/P8 are similarly connected by P wells. Active areas 536 and 537 are placed inside of N wells 534 and 535. Contacts 538 and 539 are placed perpendicularly to active areas 536 and 537. Being connected to power supply Vdd, contacts 538 and 539 enable supplying N-type wells 534 and 535 as well as rails Vdd placed inside of the insulation areas surrounding active areas 536 and 537. A contact 540 is placed above active area 530 and extends to the left. A contact 541 is placed above active area 531 and extends to the right. Being connected to ground GND, contacts 540 and 541 enable biasing rails GND respectively placed inside of insulating areas located to the left of points P5/P7 and to the right of points P6/P8.

To, as previously, disconnect bit lines BLN of points P5 and P6 from bit lines BLN of points P7 and P8, two gate areas 542 and 543 are placed perpendicularly to active areas 532 and 533. An active area 545 is placed between gate areas 542 and 543 and connects active areas 532 and 533. Active area 545 is P-type doped conversely to active areas 532 and 533 which are N-type doped. A contact 546 is placed above active area 545 and extends above insulation areas located under and above active area 545 and extends above gate areas 542 and 543. Contact 546 is grounded. Contact 546 enables biasing to ground the P wells placed under active area 545 as well as rail GND placed inside of the insulation areas covered by contact 546. The four NMOS transistors formed by gate areas 442, 443 and active areas 432 and 433 all are non-conductive since their gates are grounded.

An advantage of a SRAM such as described hereabove is that the distribution network of reference voltages Vdd and GND is placed in the insulation areas. The component integration density is unchanged and the space available for the row lines and the bit lines is strongly increased.

Of course, the present invention is likely to have various alterations, modifications, and improvements which will readily occur to those skilled in the art. In particular, it will be within the abilities of those skilled in the art to devise various circuits integrating a distribution network according to the present invention. Further, the distribution networks may be used to convey any reference voltage of an integrated circuit.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. An integrated circuit comprising a semiconductor substrate in which active areas surround or are surrounded by hollowings filled with an insulator, wherein a conductive region is embedded in the insulator of at least one hollowing, the conductive region being connected to a reference voltage and being connected to at least one neighboring element of the circuit.

2. The integrated circuit of claim 1, wherein the conductive region is connected to a conductive supply or ground line of an interconnect network.

3. The integrated circuit of claim 1, wherein said element of the circuit is a terminal of a component or a bias contact of the substrate or of a well formed in the substrate.

4. The integrated circuit of claim 1, comprising components formed in active areas, the substrate and the components being covered with an insulating protective layer, a portion of an active area adjacent to one of said at least one hollowing being connected to the conductive region of this hollowing via a metal contact placed in a single opening of the protection insulating layer and of the insulator covering the conductive layer.

5. The circuit of claim 1, wherein the semiconductor substrate is made of single-crystal silicon, said insulator being formed of silicon oxide and nitride.

6. The integrated circuit of claim 1 forming a SRAM-type memory, in which the supply and ground voltage distribution network is formed of a network of conductive regions embedded in several hollowings of the substrate, the conductive regions being connected to several source/drain areas of the MOS transistors of the memory by contacts.

7-8. (canceled)
